(19) United States
(12) Patent Application Publication
(10) Pub. No.: US 2025/0142839 A1
(43) Pub. Date: May 1, 2025

(54) MICROELECTRONIC DEVICES, MEMORY DEVICES, AND METHODS OF FORMING MICROELECTRONIC DEVICES

(71) Applicant: Micron Technology, Inc., Boise, ID (US)

(72) Inventors: Marcello Mariani, Milano (IT); Giorgio Servalli, Fara Gera D'Adda (IT)

(21) Appl. No.: 18/760,921

(22) Filed: Jul. 1, 2024

Related U.S. Application Data
(60) Provisional application No. 63/594,821, filed on Oct. 31, 2023.

(51) Int. Cl. H10B 63/00; H01L 23/528; H10N 70/00

(52) U.S. Cl. CPC H10B 63/84; H01L 23/5283; H10N 70/841

(57) ABSTRACT

A microelectronic device including first insulative structures, each first insulative structure including first sections individually having a first horizontal width in a first direction, and second sections horizontally alternating with the first sections in a second direction orthogonal to the first direction, the second sections individually having a second horizontal width in the first direction greater than the first width. First conductive structures are directly adjacent the first sections of the first insulative structures in the first direction and directly adjacent the second sections of the first insulative structures in the second direction. Second insulative structures are directly adjacent the first conductive structures and the second sections of the first insulative structures in the first direction; and second conductive structures are directly adjacent the second insulative structures in the first direction.

### CROSS-REFERENCE TO RELATED APPLICATION

This application claims the benefit under 35 U.S.C. § 119(e) of U.S. Provisional Patent Application Ser. No. 63/594,821, filed Oct. 31, 2023, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices, and to related microelectronic devices, memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

A problem with conventional microelectronic device designs arising from increasingly compact architectures is parasitic capacitance between conductive features of the microelectronic device (e.g., parasitic capacitance between the bottom electrodes of neighboring storage node elements of a memory device). Another problem with conventional designs is undesirable buildup of electrical charge in certain electrical features which can negatively impact operation of the microelectronic device.

### BRIEF DESCRIPTION OF THE DRAWINGS

FIGS. 1 through 20 are simplified, perspective (FIGS. 1, 2, 4, 5, 6, 9, 12, 14, 15, 16, 17, 18, 19, 20), simplified, partial horizontal cross-sectional (FIG. 3), and simplified, partial top plan (FIGS. 7, 8, 10, 11, 13) views of a microelectronic device structure at different processing stages of a method of forming a microelectronic device, in accordance with embodiments of the disclosure.

FIG. 21 is a schematic block diagram of an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional non-volatile memory; conventional volatile memory), but also includes an application specific integrated circuit (ASIC) (e.g., a system on a chip (SoC)), a microelectronic device combining logic and memory, and a graphics processing unit (GPU) incorporating memory.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the drawings, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, and may be perpendicular to an indicated “X” axis and/or perpendicular to an indicated “Y” axis.

As used herein, the term “intersecting directions,” when referring to the directions of structures, means and includes the structures each defining a length (e.g., longest horizontal dimension) along a direction, such that the direction of at least one of the structures would intersect (e.g., not be wholly parallel to) the direction of at least another of the structures if such directions were drawn in the same plane. For example, “intersecting directions” include, but are not limited to, perpendicular directions, with at least one structure directed along an “X” axis and at least one other structure directed along a “Y” axis, though the structures may be in different levels within a device structure.

As used herein, the term “colinear directions,” when referring to the directions of structures, means and includes the structures each defining a length (e.g., longest horizontal dimension) along a direction, such that the direction of each of the structures would wholly overlap (e.g., not divert from one another, not intersect one another, and not be wholly parallel to one another) if such directions were drawn in the same plane. For example, “colinear directions” include, but are not limited to, one structure, in one level of a device structure, directed along an “X” axis and at least one other structure, in at least one other level of the device structure, also directed along the “X” axis.

As used herein, features (e.g., structures, materials, regions, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another,

As used herein, other spatially relative terms, such as “below,” “lower,” “bottom,” “above,” “upper,” “top,” and the like, may be used for ease of description to describe the relationship of one or more feature(s) to one or more other feature(s), as illustrated in the figures. Unless otherwise specified, the spatially relative terms are intended to encompass different orientations of the materials in addition to the orientation as depicted in the figures. For example, if materials in the figures are inverted, features described as “below” or “under” or “on bottom of” other features would then be oriented “above” or “over” or “on top of” the other features. Thus, the term “below” may encompass both an orientation of above and below, depending on the context in which the term is used, which will be evident to one of ordinary skill in the art. The materials may be otherwise oriented (rotated ninety degrees, inverted, etc.) and the spatially relative descriptors used herein interpreted accordingly.

As used herein, the terms “level” and “elevation” are spatially relative terms used to describe the vertical position of a feature, as illustrated in the figures. “Lower levels” and “lower elevations” are located at relatively lower vertical positions, “higher levels” and “higher elevations” are located at relatively lower vertical positions. Unless otherwise specified, these spatially relative terms are intended to encompass different orientations of the materials in addition to the orientation as depicted in the figures. For example, feature(s) may be otherwise oriented (rotated ninety degrees, inverted, etc.) and the spatially relative descriptors used herein interpreted accordingly.

As used herein, the terms “about” and “approximately,” when either is used in reference to a numerical value for a particular parameter, are inclusive of the numerical value and a degree of variance from the numerical value that one of ordinary skill in the art would understand is within acceptable tolerances for the particular parameter. For example, “about” or “approximately,” in reference to a numerical value, may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “substantially,” when referring to a parameter, property, or condition, means and includes the parameter, property, or condition being equal to or within a degree of variance from a given value such that one of ordinary skill in the art would understand such given value to be acceptably met, such as within acceptable manufacturing tolerances. By way of example, depending on the particular parameter, property, or condition that is substantially met, the parameter, property, or condition may be “substantially” a given value when the value is at least 90.0 percent met, at least 95.0 percent met, at least 99.0 percent met, or even at least 99.9 percent met.

As used herein, “and/or” includes any and all combinations of one or more of the associated listed items.

As used herein, the singular forms “a,” “an,” and “the” are intended to include the plural forms as well, unless the context clearly indicates otherwise.

As used herein, the terms “configured” and “configuration” mean and refer to a size, shape, material composition, orientation, and arrangement of a referenced material, structure, assembly, or apparatus so as to facilitate a referenced operation or property of the referenced material, structure, assembly, or apparatus in a predetermined way.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, a Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively doped polysilicon, conductively doped germanium (Ge), conductively doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (e.g., 10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

As used herein, the term “sacrificial material” means and includes a material that is formed and/or employed during a fabrication process, but which is subsequently removed, in whole or in part, prior to completion of the fabrication process.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., wet etching, vapor etching, dry etching), ion milling, abrasive planarization (e.g., chemical-mechanical planarization (CMP)), or other known methods.

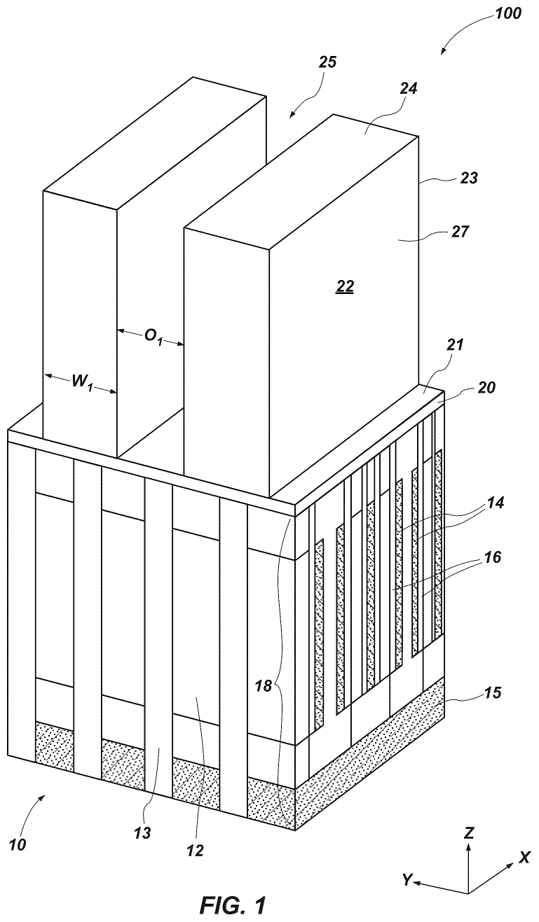

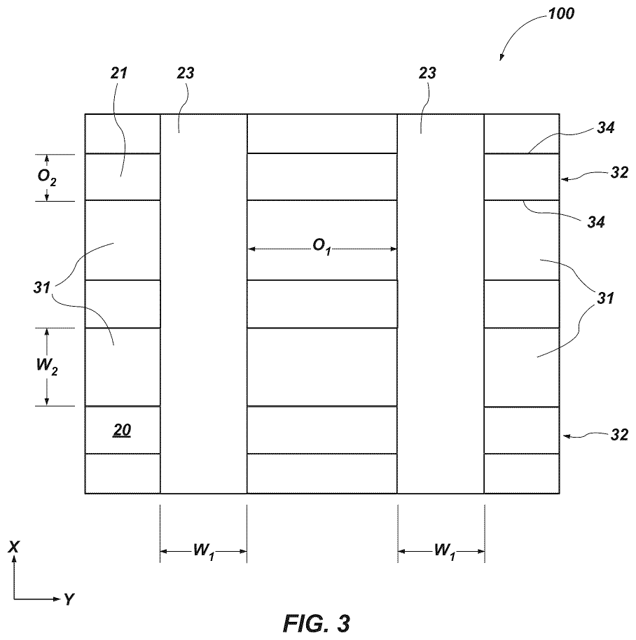

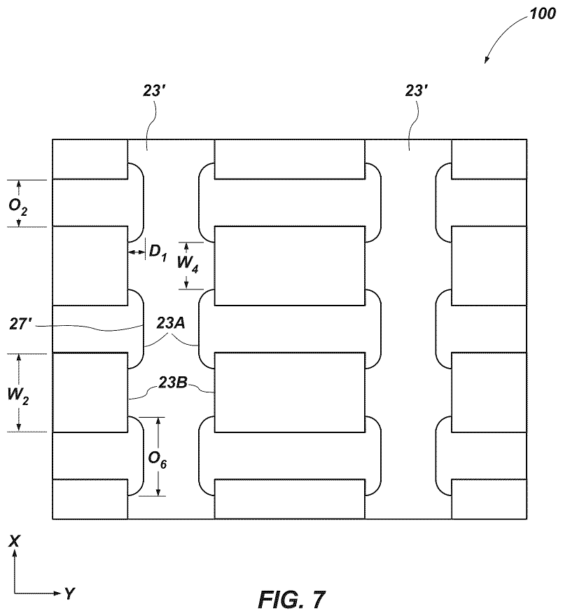

FIGS. 1 through 20 are simplified, partial perspective (FIGS. 1, 2, 4, 5, 6, 9, 12, 14, 15, 16, 17, 18, 19, 20), simplified, partial horizontal cross-sectional (FIG. 3), and simplified, partial top plan (FIGS. 7, 8, 10, 11, 13) views of a microelectronic device structure (e.g., a memory device structure) at different processing stages of a method of forming a microelectronic device (e.g., a memory device, such as one of a dynamic random-access memory (DRAM) device, a high-resistive random-access memory (HRAM) device, a ferroelectric random-access memory (FeRAM) device, a synchronous dynamic random-access memory (SDRAM) device, a resistive random-access memory (RRAM) device, a conductive bridge random-access memory (conductive bridge RAM) device, a magnetic random-access memory (MRAM) device, a phase change random-access memory (PCRAM) device, a spin torque-transfer random-access memory (STTRAM) device), in accordance with embodiments of the disclosure. With the description provided below, it will be readily apparent to one of ordinary skill in the art that the methods described herein may be used to form various microelectronic devices.

Referring to FIG. 1, a microelectronic device structure 100 may be formed to include an access device array 10 having access devices 18 (e.g., thin film transistors, vertical transistors) operatively arranged therein. As described in further detail below, each of the access devices 18 of the access device array 10 may respectively include a semiconductor pillar 12 forming a channel region, a source region, and a drain region; at least one gate electrode 14 horizontally neighboring (e.g., in the X-direction) the semiconductor pillar 12; and gate dielectric material 16 horizontally interposed (e.g., in the X-direction) between the semiconductor pillar 12 and the gate electrode 14.

The semiconductor pillar 12 of an individual access device 18 may be formed of and include one or more semiconductor material(s). An individual semiconductor pillar 12 may include a source region, a drain region, and a channel region vertically interposed between the source region and the drain region. The source region and the drain region may respectively be doped with one or more conductivity-enhancing species (e.g., n-type dopant(s) or p-type dopant(s)); and the channel region may be doped with one or more other conductivity-enhancing species, of opposite type relative to those of the source region and the drain region, or may be substantially undoped.

The gate electrode(s) 14 of an individual access device 18 may be formed of and include one or more conductive material(s). In some embodiments, the gate electrode(s) 14 are individually formed of and include one or more of W and TiNₓ. The gate electrode(s) 14 may horizontally extend (e.g., in the Y-direction) in parallel. The gate electrodes 14 may also be referred to herein as local word lines or local access lines. An individual gate electrode 14 may be shared by multiple access devices 18 of the access device array 10.

The gate dielectric material 16 of an individual access device 18 may be formed of and include one or more insulative material(s). In some embodiments, the gate dielectric material 16 is formed of and includes a dielectric oxide material (e.g., SiOₓ).

Still referring to FIG. 1, access device insulative structures 13 may be disposed horizontally between (e.g., in the Y-direction) neighboring access devices 18. The access device insulative structures 13 may be formed of and include one or more insulative material(s). With reference to FIG. 1, the access devices 18 and the access device insulative structures 13 extend horizontally and alternate with one another in the Y-direction.

An access device array 10 also includes one or more conductive line

structures 15 (e.g., bit line structures, data line structures, digit line structures). The conductive line structures 15 may be formed of one or more conductive materials, such as described hereinabove. The conductive line structures 15 may be coupled to the access devices 18. Each conductive line structure 15 may be coupled to a respective group (e.g., row) of the access devices 18. In some embodiments, the conductive line structures 15 are coupled to drain regions of the semiconductor pillars 12 of the access devices 18.

A first mask material 20 may be formed on or over upper surfaces of the access device array 10, such as on or over upper surfaces of the semiconductor pillars 12, the gate dielectric material 16, and the access device insulative structures 13. In some embodiments, the first mask material 20 is formed of and includes dielectric material, such as dielectric nitride material (e.g., silicon nitride). The first mask material 20 may be formed over substantially the entirety of the access device array 10. In some embodiments, an upper surface 21 of the first mask material 20 is substantially planar. The upper surface 21 of the first mask material 20 may be formed using a suitable planarization process (e.g., CMP).

With continued reference to FIG. 1, first insulative structures 23 may be formed on or over the first mask material 20. The first insulative structures 23 may horizontally extend in parallel in the X-direction, and may be horizontally separated from one another in the Y-direction by first trenches 25. The first trenches 25 may horizontally alternate with the first insulative structures 23 in the Y-direction. The first insulative structures 23 may respectively be formed of and include a first insulative material 22. In some embodiments, the first insulative material 22 comprises an oxide dielectric material (e.g., SiOₓ). In additional embodiments, the first insulative material 22 comprises a low-K dielectric material. In some embodiments, the first insulative structures 23 have upper surfaces 24 that are substantially co-planar with one another.

Horizontal boundaries of the first trenches 25 in the Y-direction may be at least partially defined by sidewalls 27 of the first insulative structures 23. In addition, lower vertical boundaries of the first trenches 25 in the Z-direction may be at least partially defined by the upper surface 21 of the first mask material 20. The first insulative structures 23 may individually exhibit a first width W₁ in the Y-direction. The first width W₁ may be within a range of from about 10 nm to about 40 nm (e.g., about 20 nm). In addition, a first offset O₁ in the Y-direction between neighboring first insulative structures 23, which corresponds to a width in the Y-direction of an individual first trench 25, may be within a range of from about 10 nm to about 40 nm (e.g., about 20 nm). In some embodiments, the first insulative structures 23 partially horizontally overlap (e.g., in the Y-direction) the semiconductive pillars 12 of the access devices 18, and also partially horizontally overlap (e.g., in the Y-direction) the access device insulative structures 13.

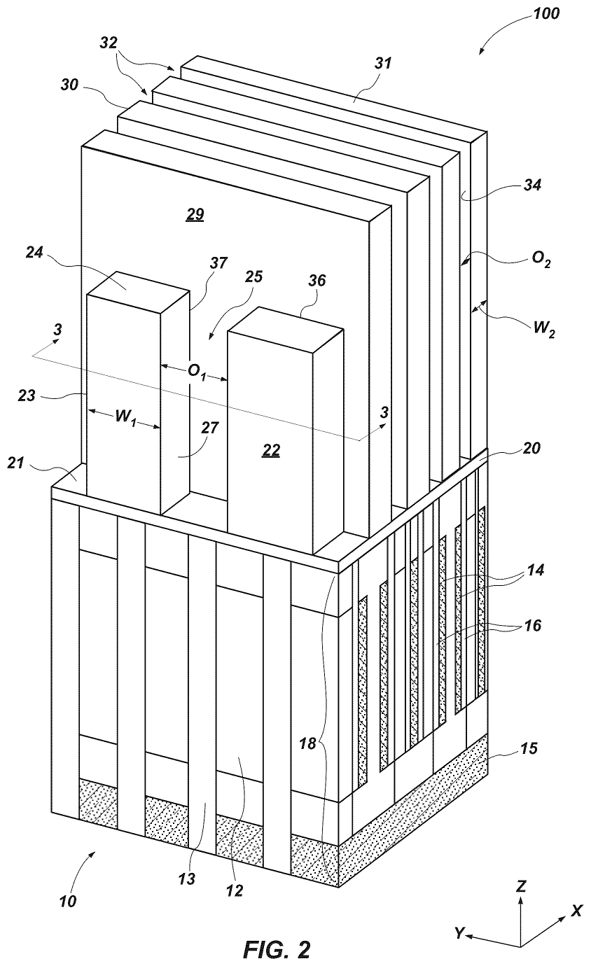

Referring next to FIG. 2, a second mask material 29 may be formed (e.g., non-conformally deposited) on or over the first insulative structures 23 of the microelectronic device structure 100, and may then be patterned to form second mask structures 30. For instance, the second mask material 29 may be formed on or over the first insulative structures 23, and may substantially fill the first trenches 25, and a first material removal process (e.g., a first process including photolithographic patterning and etching) may be effectuated to remove portions of the second mask material 29 and form the second mask structures 30 from remaining portions of the second mask material 29. The second mask structures 30 may have upper surfaces 31 that are substantially co-planar with one another. In some embodiments, the second mask material 29 is formed of and includes photoresist material. In additional embodiments, the second mask material 29 is formed of and includes amorphous carbon. FIG. 3 is a horizontal cross-sectional view of a portion of the microelectronic device structure 100 at the processing stage of FIG. 2 along lines 3-3 thereof.

Referring collectively to FIGS. 2 and 3, the second mask structures 30 may be formed to extend horizontally in parallel in the Y-direction, and may be horizontally separated from one another in the X-direction by second trenches 32. Horizontal boundaries of the second trenches 32 in the X-direction may be at least partially defined by sidewalls 34 of the second mask structures 30. In addition, lower vertical boundaries of the second trenches 32 in the Z-direction may be non-planar and may be at least partially defined by the upper surface 21 of the first mask material 20 and the upper surfaces 24 of the first insulative structures 23. The second mask structures 30 may individually exhibit a second width W₂ in the X-direction. The second width W₂ may be within a range of from about 10 nm to about 40 nm (e.g., about 20 nm). In addition, a second offset O₂ in the X-direction between neighboring second mask structures 30, which corresponds to a width in the X-direction of an individual second trench 32, may be within a range of from about 5 nm to about 25 nm (e.g., about 12 nm).

With reference again to FIG. 2, upper interfaces 36 may be formed between the upper surfaces 24 of the first insulative structures 23 and the portions of the second mask structures 30 on the upper surfaces 24. Inner interfaces 37 are formed between the sidewalls 27 of the first insulative structures 23 and additional portions of the second mask structures 30 on the sidewalls 27, as also shown in FIG. 2.

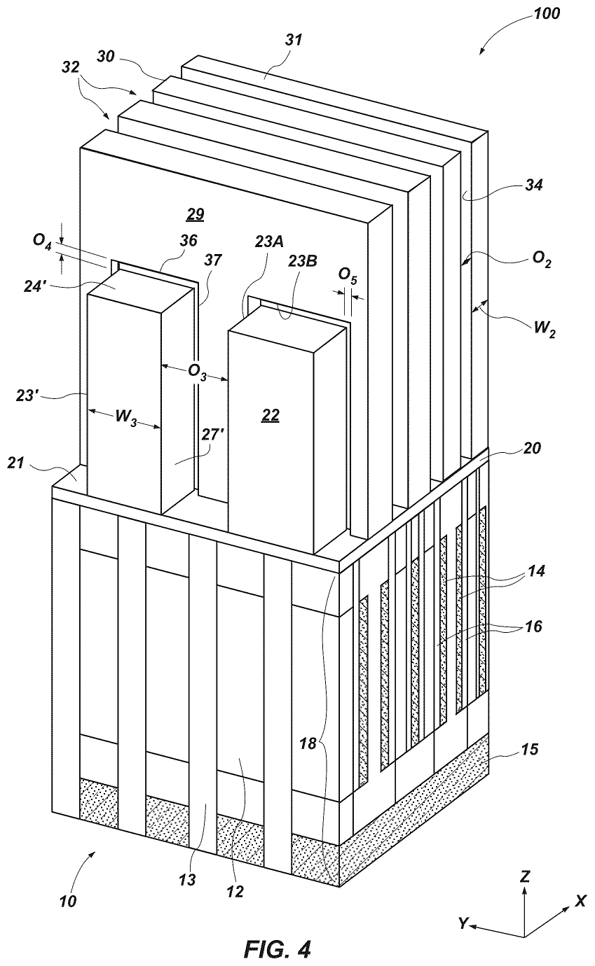

Referring next to FIG. 4, portions of the first insulative material 22 are removed (e.g., trimmed) from the first insulative structures 23 (FIGS. 1 through 3) to form modified first insulative structures 23′. The removal process may partially horizontally and vertically recess the first insulative structures 23 (FIGS. 1 through 3). The modified first insulative structures 23′ may respectively include recessed sections 23A and projecting sections 23B horizontally interposed between the recessed sections 23A in the X-direction.

Removal of portions of the first insulative material 22 may be effectuated by using an etching process (e.g., wet etching, dry etching) that selectively removes exposed portions of the first insulative material 22 from the first insulative structures 23 (FIGS. 1 through 3) relative to the first mask material 20 and the second mask structures 30. More particularly, the first insulative material 22 of the first insulative structures 23 (FIGS. 1 through 3) may be removed at substantially greater rates than the first mask material 20 or the second mask material 29 are removed. In some embodiments, an isotropic etching process (e.g., hydrofluoric acid wet etching) is utilized to trim portions of the first insulative material 22 from the first insulative structures 23 (FIGS. 1 through 3), including portions of the first insulative material 22 outside and inside of horizontal areas of the second mask structures 30. In additional embodiments, an anisotropic etching process (e.g., dry etching) is utilized to remove portions of the first insulative material 22 to form the modified first insulative structures 23′, while other portions of the first insulative material 22 vertically underlying and within horizontal areas of the second mask structures 30 may substantially remain after the anisotropic etching process is completed.

As shown in FIG. 4, for an individual modified first insulative structure 23′, fourth offsets O₄ may be formed between portions of modified upper surfaces 24′ (e.g., non-planar, partially recessed upper surfaces) of the modified first insulative structures 23′ within horizontal areas of the recessed sections 23A and the upper interfaces 36; and fifth offsets O₅ may be formed between portions of modified sidewalls 27′ (e.g., non-planar, partially recessed sidewalls) of the modified first insulative structures 23′ within horizontal areas of the recessed sections 23A and the inner interfaces 37. The dimensions of the fourth offsets O₄ and the fifth offsets O₅ may be increased or decreased by increasing or decreasing the amount of time of the isotropic etching process, respectively.

The removal of portions of the first insulative material 22 from the first insulative structures 23 (FIGS. 1 through 3) may result in the recessed sections 23A of the modified first insulative structures 23′ individually having a third width W₃ in the Y-direction smaller than the first width W₁; and the projecting sections 23B of the modified first insulative structures 23′ individually maintaining the first width W₁ in the Y-direction. The third width W₃ of an individual recessed section 23A of an individual modified first insulative structure 23′ may be within a range of from about 5 nm to about 30 nm (e.g., about 15 nm). In addition, the recessed sections 23A of the modified first insulative structures 23′ may have relatively smaller vertical heights in the Z-direction than the projecting sections 23B of the modified first insulative structures 23′. In addition, third offsets O₃, in the Y-direction, between the recessed sections 23A of horizontally neighboring modified first insulative structures 23′ may be greater than the first offsets O₁, in the Y-direction, maintained between the projecting sections 23B of the horizontally neighboring modified first insulative structures 23′. The third offset O₃ may be within a range of from about 20 nm to about 60 nm (e.g., about 30 nm).

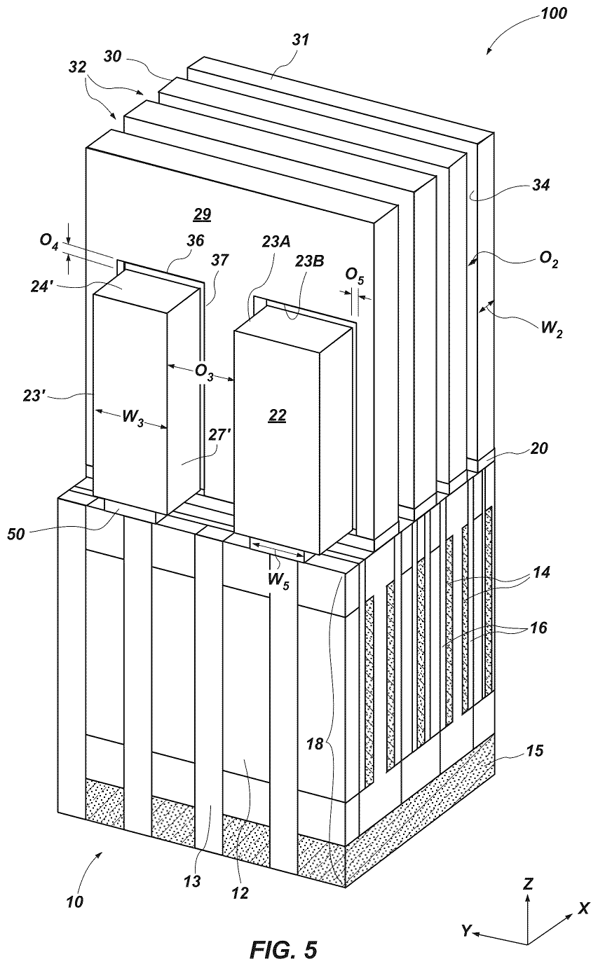

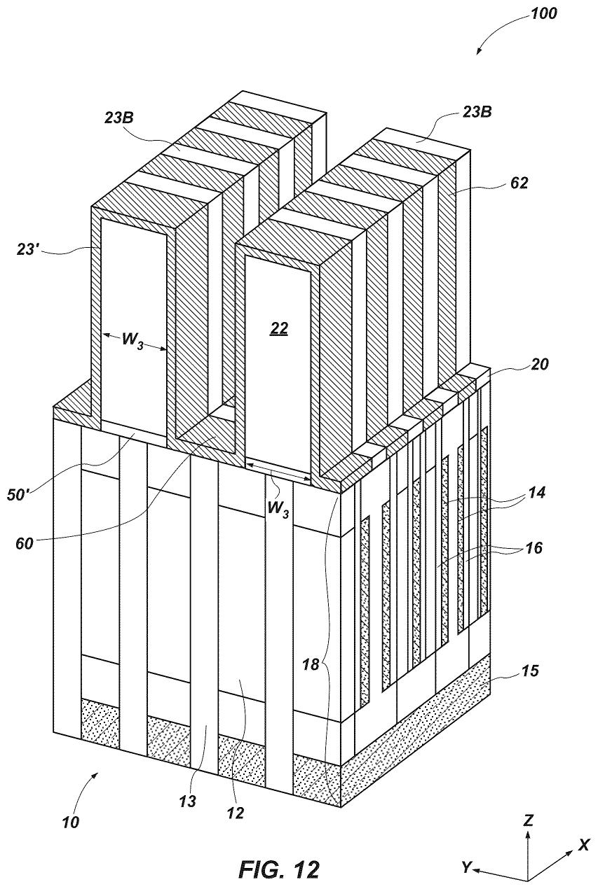

Following the formation of the modified first insulative structures 23′, portions of the first mask material 20 may be selectively removed relative to the modified first insulative structures 23′ and the second mask structures 30. The removal of portions of the first mask material 20 partially exposes upper surfaces of the access device array 10, such as on or over upper surfaces of the semiconductor pillars 12, the gate dielectric material 16, and the access device insulative structures 13. In some embodiments, an isotropic etching process (e.g., hydrofluoric acid wet etching) is utilized to selectively remove portions of the first mask material 20. Accordingly, at least some portions of the first mask material 20 may be removed from under the modified first insulative structures 23′ to form step structures 50 individually exhibiting a fifth width W₅ in the Y-direction, as shown in FIG. 5. The fifth width W₅ may be less than the third width W₃ of the recessed sections 23A of the modified first insulative structures 23′. Alternatively, an anisotropic etching process (e.g., dry etching) may be utilized to selectively remove portions of the first mask material 20, in which case the portions of the first mask material 20 disposed under the first insulative structures 23 remain and form step structures 50′ (FIGS. 12 and 14 through 20) individually exhibiting the third width W₃.

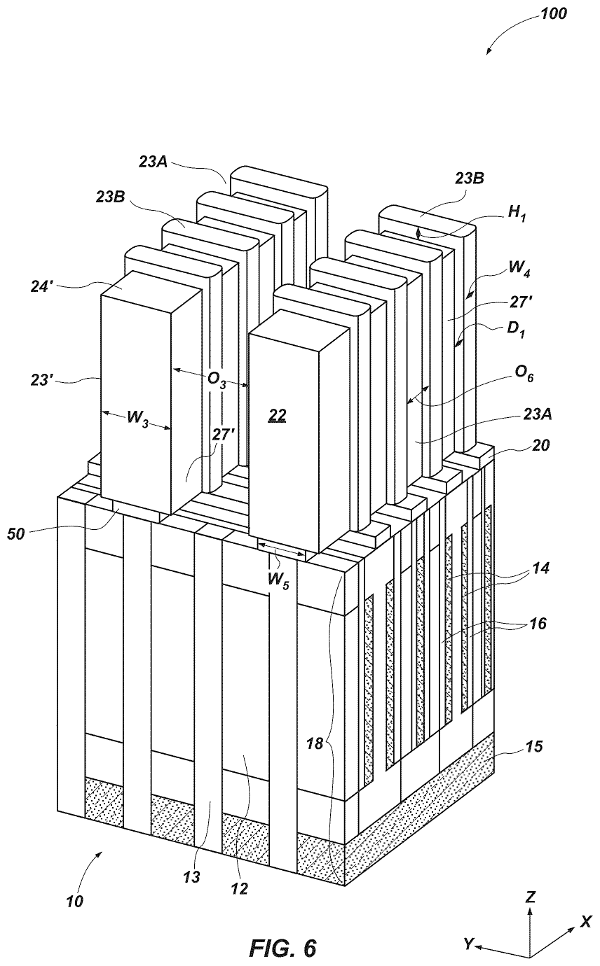

With reference to FIG. 6, a further material removal process (e.g., a mask stripping process) may be utilized to remove the remaining portions of the second mask structures 30 (FIG. 5). The removal of the second mask structures 30 (FIG. 5) may substantially expose the modified upper surfaces 24′ and modified sidewalls 27′ of the modified first insulative structures 23′.

As shown in FIG. 6, following the removal of portions of the first insulative material 22 from the first insulative structures 23 (FIGS. 1 through 3), and removal of the second mask structures 30, the projecting sections 23B of the modified first insulative structures 23′ may be substantially exposed. As shown in FIG. 6, an individual projecting section 23B may exhibit a fourth width W₄ in the X-direction. The fourth width W₄ may be within a range of from about 5 nm to about 25 nm (e.g., about 12 nm). As also shown in FIG. 6, projecting sections 23B horizontally neighboring one another in the X-direction (and substantially aligned with one another in the Y-direction) may be horizontally offset from one another in the X-direction by a sixth offset O₆. The sixth offset O₆ may be within a range of from about 10 nm to about 40 nm (e.g., about 20 nm). With continued reference to FIG. 6, the projecting sections 23B horizontally extend, in the Y-direction, from the recessed sections 23A by a first depth D₁, corresponding to the fifth offset O₅ (FIGS. 4 and 5). In some embodiments, the first depth D₁ is within a range of from about 2 nm to about 10 nm (e.g., about 4 nm). In addition, the projecting sections 23B vertically extend, in the Z-direction, from the recessed sections 23A by a first height H₁, corresponding to the fourth offset O₄ (FIGS. 4 and 5). In some embodiments, the first height H₁ is within a range of from about 2 nm to about 10 nm (e.g., about 4 nm).

FIG. 7 is a simplified, partial top plan view of a portion of the microelectronic device structure 100 at the processing stage of FIG. 6, wherein some features are not shown for clarity and ease of understanding the drawings and related description. As shown in FIG. 7, the modified first insulative structures 23′ horizontally extend in parallel in the X-direction and are separated from one another in the Y-direction. As also shown in FIG. 7, the modified sidewalls 27′ of the modified first insulative structures 23′ may have arcuate (e.g., rounded) transitions between the recessed sections 23A and the projecting sections 23B thereof.

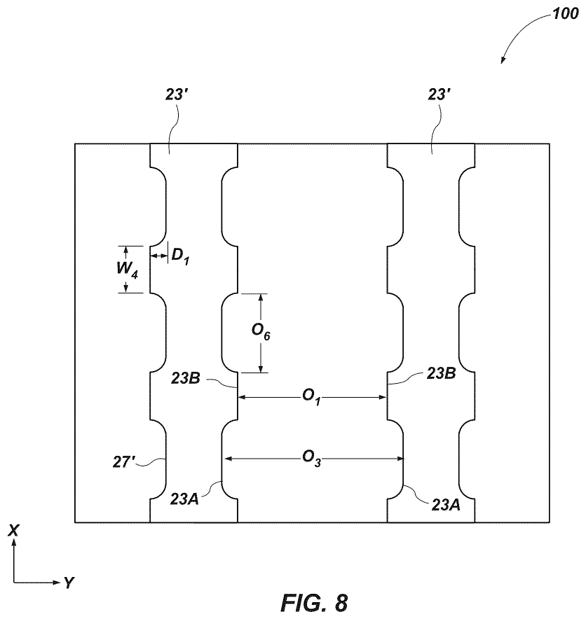

FIG. 8 is an additional simplified, partial top plain view of a portion of the microelectronic device structure 100 at the processing stage of FIG. 6, wherein additional features are not shown for clarity and ease of understanding the drawings and related description. As shown in FIG. 8, the projecting sections 23B of modified first insulative structures 23′ horizontally neighboring one another in the Y-direction are spaced apart from one another in the Y-direction by the first offset O₁; and the recessed sections 23A of modified first insulative structures 23′ horizontally neighboring one another in the Y-direction are spaced apart from one another in the Y-direction by the third offset O₃.

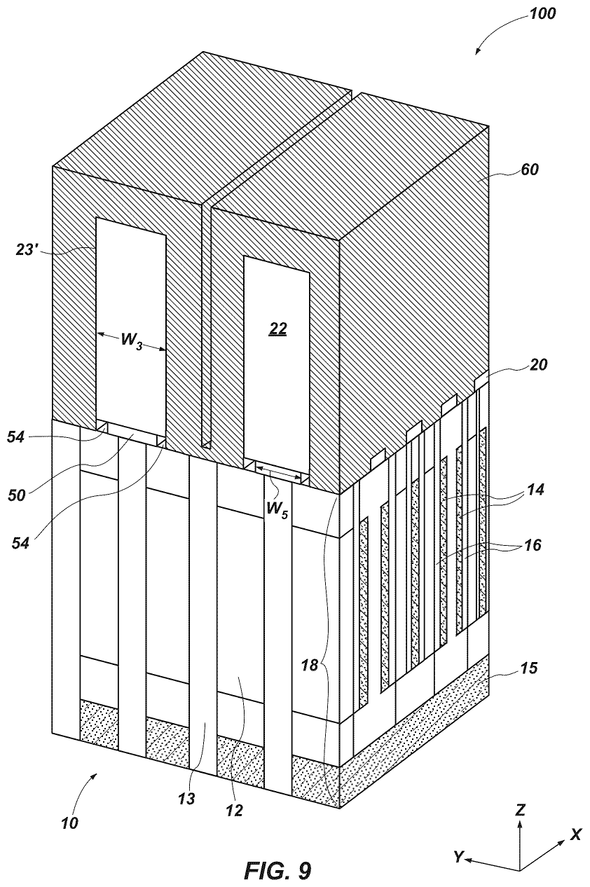

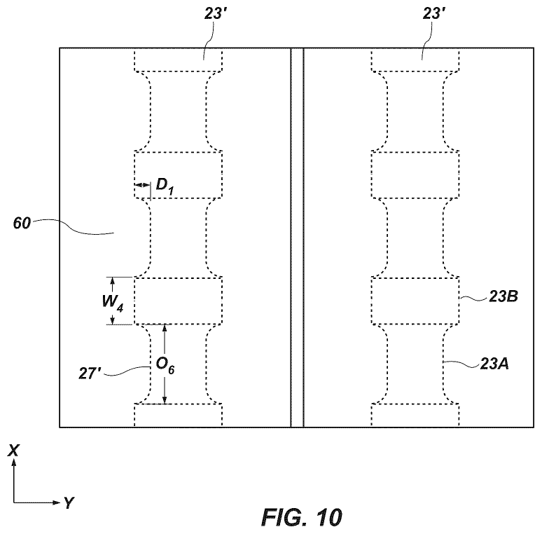

Referring next to FIG. 9, a first conductive material 60 may be formed (e.g., conformally deposited) on or over the modified first insulative structures 23′. The first conductive material 60 may substantially cover and continuously extend across the recessed sections 23A and the projecting sections 23B (FIGS. 6 through 8) of the modified first insulative structures 23′. In some embodiments, the first conductive material 60 includes metallic material (e.g., titanium, tungsten, alloys thereof). In additional embodiments, the first conductive material 60 comprises a conductive metal-containing material (e.g., a conductive metal nitride, a conductive metal silicon nitride, a conductive metal oxide). In some embodiments, air gaps 54 may remain between the step structures 50 vertically underlying the modified first insulative structures 23′ and horizontally neighboring (e.g., in the Y-direction) portions of the first conductive material 60. FIG. 10 is a simplified, partial top view of a portion of the microelectronic device structure 100 at the processing stage of FIG. 9. As shown in FIG. 10, the first conductive material 60 substantially covers and continuously extends over and across the projecting sections 23B and into the recessed sections 23A of the modified first insulative structures 23′.

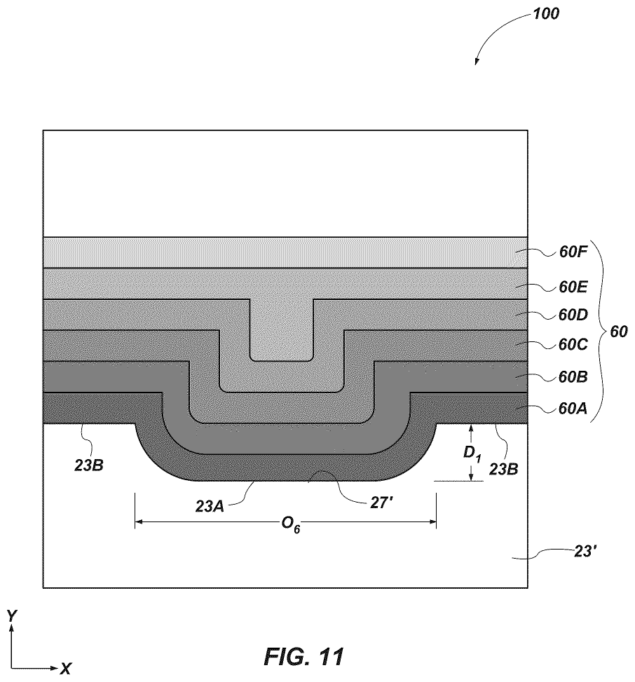

FIG. 11 is a simplified, partial top plan view of a portion of the microelectronic device structure 100 at the processing stage of FIG. 9, which shows one embodiment of forming the first conductive material 60 on or over surfaces (e.g., the sidewalls 27′, the recessed sections 23A, the projecting sections 23B) of the modified first insulative structures 23′. In some embodiments, the first conductive material 60 is formed on or over the surfaces of the modified first insulative structures 23′ by way of conformal deposition, such that the first conductive material 60 conforms to the non-planar topographies of the surfaces (e.g., the sidewalls 27′, the recessed sections 23A, the projecting sections 23B) of the modified first insulative structures 23′. As shown in FIG. 11, multiple conformal layers 60A-60F of the first conductive material 60 having a substantially uniform thickness (e.g., about 1 to about 6 nanometers, about 2 to about 4 nm, about 2 nm) may be conformally deposited over the modified first insulative structures 23′. While six (6) conformal layers 60A-60F are shown in FIG. 11, any desirable quantity of conformal layers may be employed to form the first conductive material 60.

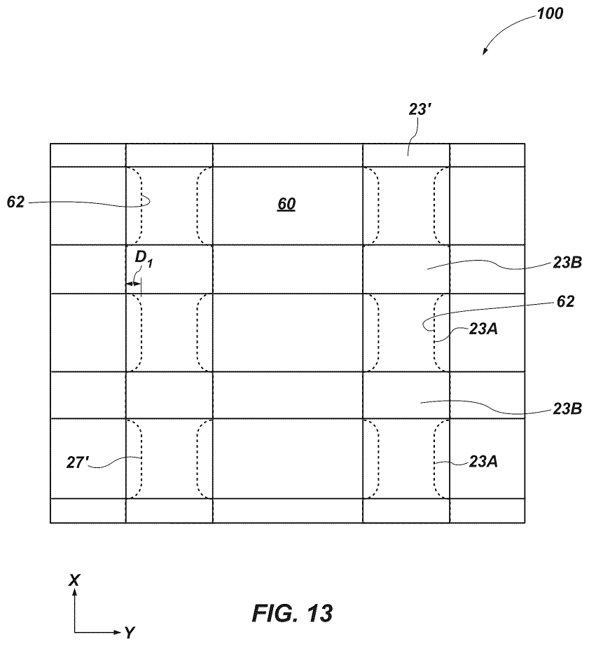

Referring next to FIG. 12, which depicts a simplified, partial perspective view of the microelectronic device structure 100 at a processing stage following that previously described with reference to FIGS. 9 through 11, another material removal process (e.g., a photolithographic patterning and etching process) may be utilized to remove portions of the first conductive material 60 and form first conductive structures 62 from remaining portions of the first conductive material 60. The material removal process may remove portions of the first conductive material 60 extending beyond outer boundaries, in the Y-direction and the Z-direction, of the projecting sections 23B of the modified first insulative structures 23′. Outer boundaries (e.g., outer surfaces) of the first conductive structures 62 may be substantially coplanar with outer boundaries (e.g., outer surfaces) of the projecting sections 23B of the modified first insulative structures 23′. As shown in FIG. 12, the first conductive structures 62 may be substantially confined within horizontal boundaries in the X-direction of the recessed sections 23A (FIGS. 10 and 11) of the modified first insulative structures 23′. The first conductive structures 62 may horizontally alternate with the projecting sections 23B of the modified first insulative structures 23′ in the X-direction. As shown in FIG. 12, the first conductive structures 62 may individually continuously extend, in the Y-direction, over and between modified first insulative structures 23′ horizontally neighboring one another in the Y-direction. The projecting sections 23B of the modified first insulative structures 23′ may reduce (e.g., minimize) parasitic capacitance between first conductive structures 62 horizontally neighboring one another in the X-direction. FIG. 13 is a simplified, partial top view of a portion of the microelectronic device structure 100 at the processing stage of FIG. 12. As shown in FIG. 13, the first conductive structures 62 are substantially confined within horizontal boundaries in the X-direction of the recessed sections 23A of the modified first insulative structures 23′. Further, the first conductive structures 62 horizontally alternate with the projecting sections 23B of the modified first insulative structures 23′ in the X-direction.

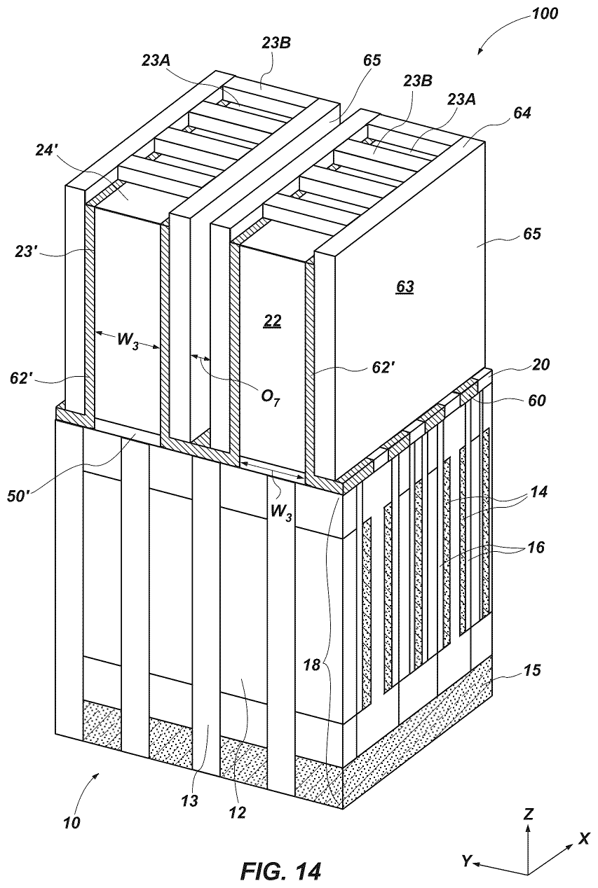

Referring next to FIG. 14, sacrificial structures 63 may be formed on or over the first conductive structures 62 (FIG. 12) and the modified first insulative structures 23′. The sacrificial structures 63 may horizontally extend in parallel in the X-direction, and pairs of the sacrificial structures 63 may be horizontally interposed between modified first insulative structures 23′ horizontally neighboring one another in the Y-direction. In some embodiments, a sacrificial material is formed on or over portions of the first conductive structures 62 and the modified first insulative structures 23′, and then a further material removal process (e.g., a further process including photolithographic patterning and etching) may be effectuated to form the sacrificial structures 63. The sacrificial structures 63 may individually include an upper surface 64 and outer sidewalls 65, which may each be substantially planar. As shown in FIG. 14, pairs of the sacrificial structures 63 horizontally interposed between modified first insulative structures 23′ horizontally neighboring one another in the Y-direction may be separated from one another in the Y-direction by a seventh offset O₇. The seventh offset O₇ may be within a range of from about 5 nm to about 15 nm (e.g., about 10 nm).

In addition, at the processing stage of FIG. 14, the upper portions of the first conductive structures 62 (FIG. 12) within horizontal areas of the recessed sections 23A of the modified first insulative structures 23′ may be removed to expose recessed sections 23A of the modified first insulative structures 23′ and form modified first conductive structures 62′ from remaining portions of the first conductive material 60.

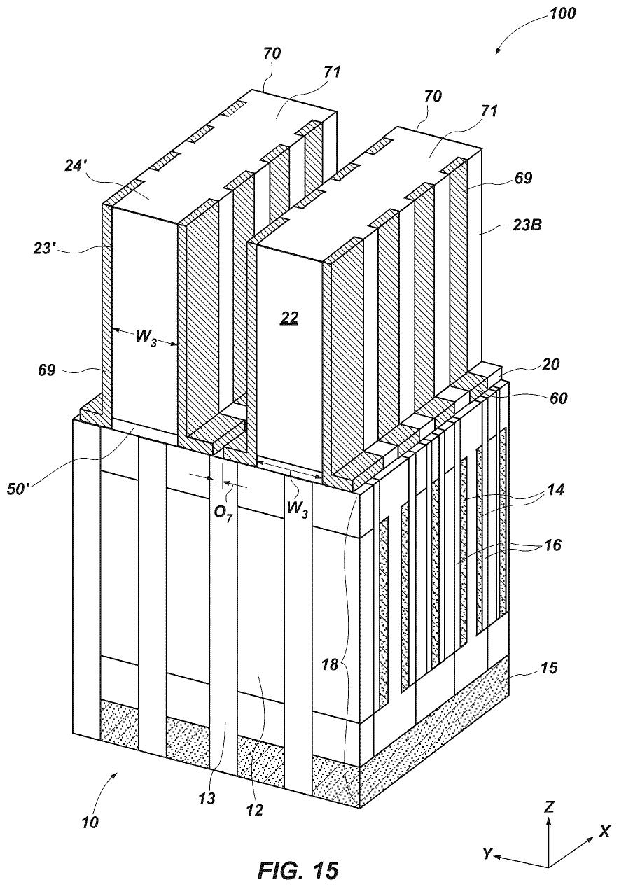

With reference to FIG. 15, an additional material removal process (e.g., dry etching) may be employed to remove portions of the modified first conductive structures 62′ (FIG. 14) and form first conductive plate structures 69 therefrom. The additional material removal process may remove portions of the modified first conductive structures 62′ (FIG. 14) exposed between pairs of the sacrificial structures 63 (FIG. 14) horizontally interposed between modified first insulative structures 23′ horizontally neighboring one another in the Y-direction. The first conductive plate structures 69 may individually exhibit an L-shaped vertical cross-sectional shape, with lower portions (e.g., lower legs) of first conductive plate structures 69 horizontally neighboring one another in the Y-direction separated from one another by a distance equal to the seventh offset O₇. The additional material removal process may also be utilized to remove portions of the first mask material 20 exposed by the sacrificial structures 63 (FIG. 14). Following the formation of the first conductive plate structures 69, the sacrificial structures 63 (FIG. 14) may be removed (e.g., stripped), and assemblies 70 including planarized surfaces 71 may be formed utilizing a suitable planarization process (e.g., CMP). The planarized surfaces 71 may include substantially coplanar upper surfaces of the first conductive plate structures 69 and the modified upper surfaces 24′ of the modified first insulative structures 23′. The planarization process may remove upper portions of the projecting sections 23B of modified first insulative structures 23′.

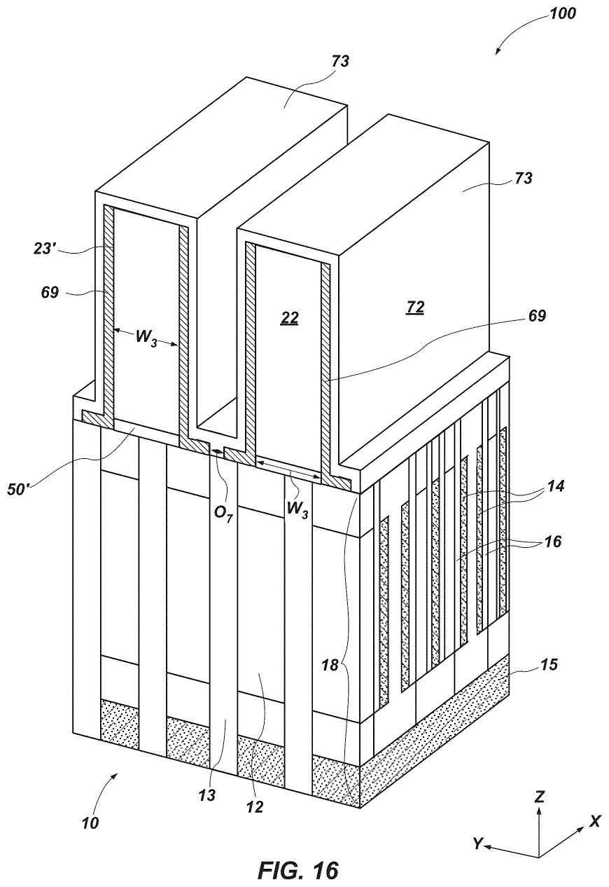

Referring next to FIG. 16, a second insulative material 72 may be formed (e.g., conformally deposited) on or over the assemblies 70 (FIG. 15). The second insulative material 72 may substantially cover and continuously extend across and between the first conductive plate structures 69 and the modified first insulative structures 23′ forming second insulative structures 73 thereover. In some embodiments, the second insulative material 72 is formed to a thickness within a range of from about 3 nm to about 10 nm (e.g., 5 nm). In some embodiments, the second insulative material 72 is formed of and includes a high-K dielectric material. The second insulative material 72 may be doped or may be substantially undoped. In some embodiments, the second insulative material 72 comprises ferroelectric material.

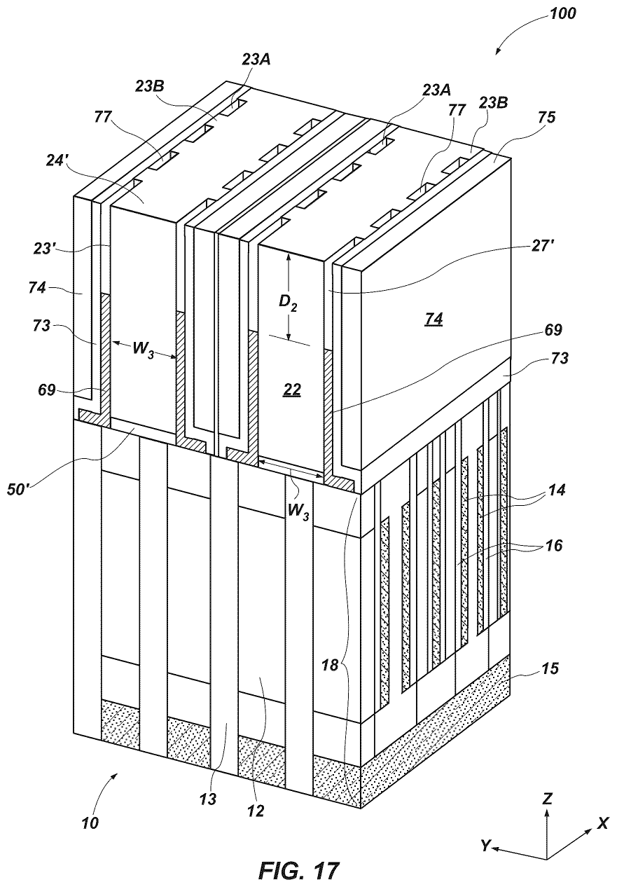

Referring next to FIG. 17, additional sacrificial structures 74 may be formed (e.g., non-conformally deposited) on or over outer sidewalls of the second insulative structures 73. The additional sacrificial structures 74 may individually be formed to have a substantially planar upper surface 75. In addition, as shown in FIG. 17, upper portions of the second insulative structures 73 may be removed to allow the upper portions of the first conductive plate structures 69 to be selectively removed through an etching process to form first slots 77. The first slots 77 may be horizontally interposed between the second insulative structures 73 and the modified sidewalls 27′ of the modified first insulative structures 23′ in the Y-direction, and may individually extend from and between remainders of neighboring projecting sections 23B of the modified first insulative structures 23′ in the X-direction. The first slots 77 may individually vertically extend in the Z-direction to a second depth D₂ from the modified upper surfaces 24′ of the modified first insulative structures 23′. In some embodiments, the second depth D₂ of the first slots 77 is within a range of from about 10 nm to about 60 nm, or from about 20 nm to about 40 nm.

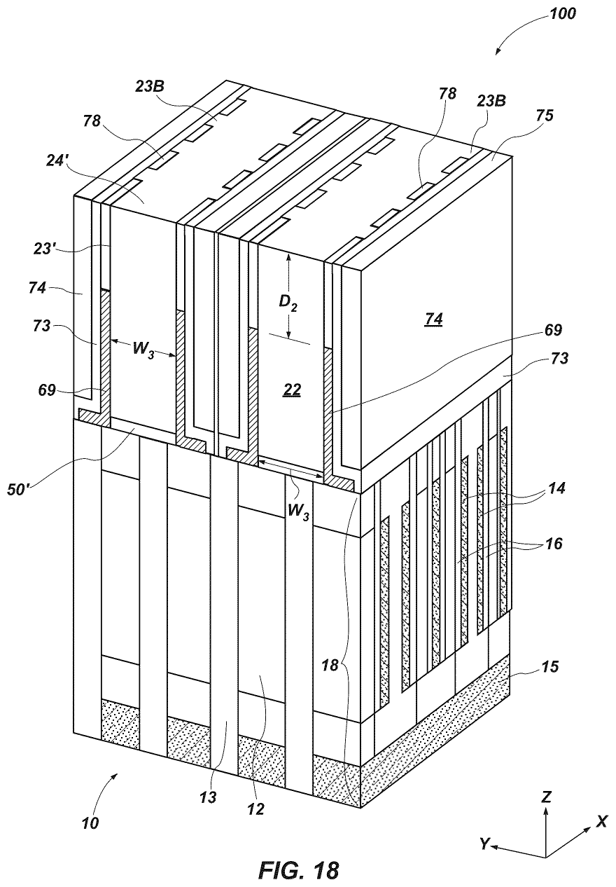

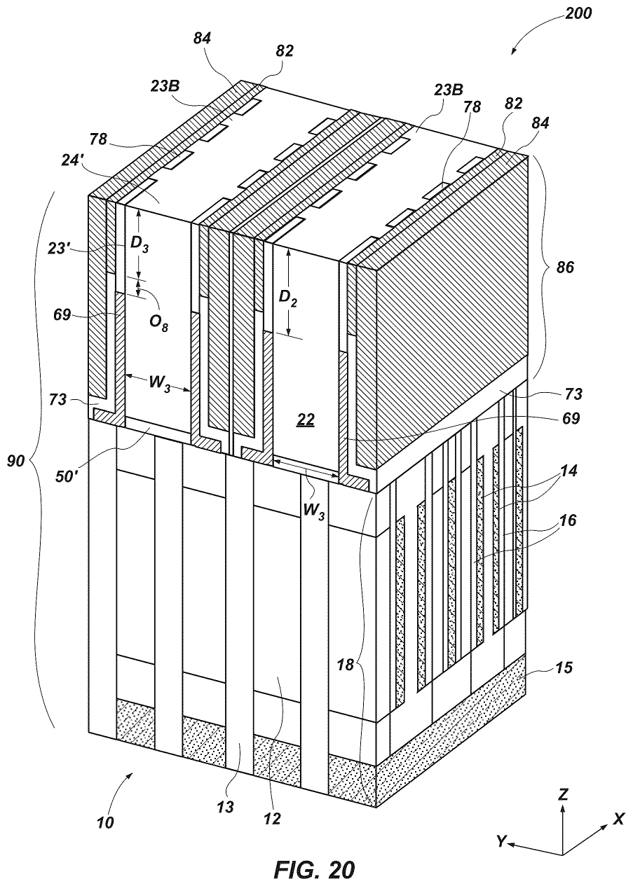

Referring next to FIG. 18, resistive structures 78 may be formed in the first slots 77 (FIG. 17). The resistive structures 78 may individually be formed of and include conductive material. In some embodiments, the resistive structures 78 are formed of and include a conductive metal-containing nitride (e.g., titanium nitride, oxidized titanium nitride, titanium silicon nitride). The resistive structures 78 may individually be formed to a depth substantially equal to the second depth D₂ of the corresponding first slots 77 (FIG. 17) (e.g., from about 10 nm to about 60 nm, from about 20 nm to about 40 nm). The resistive structures 78 at least partially facilitate a preselected resistance between the first conductive plate structures 69 and second conductive plate structures 82 (FIG. 20) to subsequently be formed, as described in more detail below. An amount of resistance between the first conductive plate structures 69 and second conductive plate structures 82 (FIG. 20) may be tailored for a particular application, in part, by selecting the resistivity of the material used to form the resistive structures 78, as well as by selecting the second depths D₂ of the first slots 77 in which the resistive structures 78 are formed. As shown in FIG. 18, upper surfaces of the resistive structures 78 may be formed (e.g., using a planarization process) to be substantially coplanar with modified upper surfaces 24′ of the modified first insulative structures 23′, the second insulative structures 73, and the additional sacrificial structures 74.

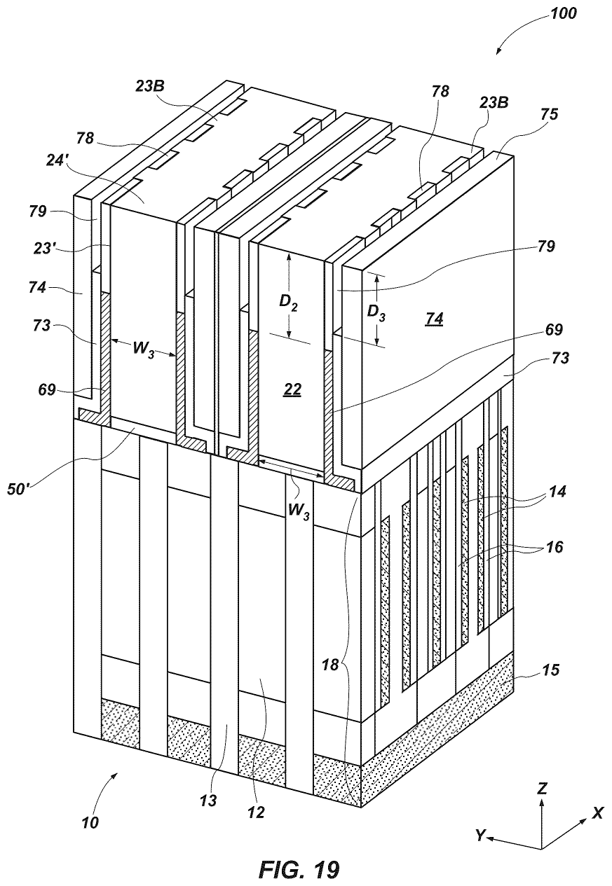

With reference to FIG. 19, upper portions of the second insulative structures 73 may be selectively removed through another etching process to form second slots 79. The second slots 79 may horizontally extend in parallel in the X-direction, and may be horizontally interposed between the additional sacrificial structures 74 and the resistive structures 78 (as well as remainders of the projecting sections 23B of the modified first insulative structures 23′) in the Y-direction. The second slots 79 may individually vertically extend in the Z-direction to a third depth D₃ extending from the modified upper surfaces 24′ of the modified first insulative structures 23′. The third depth D₃ may be shallower than that of the second depth D₂. In some embodiments, the third depth D₃ of the second slots 79 is within a range of from about 10 nm to about 40 nm, or from about 20 nm to about 30 nm.

Referring to FIG. 20, second conductive plate structures 82 may be formed in the second slots 79 (FIG. 19). The second conductive plate structures 82 may be formed of and include one or more conductive materials. In some embodiments, the second conductive plate structures 82 comprise metallic material (e.g., titanium, tungsten). In additional embodiments, the second conductive plate structures 82 comprise conductive metal-containing material (e.g., conductive metal nitride, conductive metal silicon nitride, conductive metal oxide). The second conductive plate structures 82 may be formed to depths substantially equal to the third depths D₃ of the corresponding second slots 79 (FIG. 19) (e.g., from about 10 nm to about 40 nm, from about 20 nm to about 30 nm). The second conductive plate structures 82 may be substantially confined within the second slots 79 (FIG. 19). The second conductive plate structures 82 may horizontally extend in parallel in the X-direction, and may be horizontally interposed between the additional sacrificial structures 74 (FIGS. 17 through 19) and the resistive structures 78 (as well as remainders of the projecting sections 23B of the modified first insulative structures 23′) in the Y-direction.

After the second conductive plate structures 82 have been formed, the additional sacrificial structures 74 (FIGS. 17 through 19) are removed (e.g., stripped) and replaced with third conductive plate structures 84. The third conductive plate structures 84 may comprise one or more conductive materials, which may or may not be the same as the conductive materials from which the second conductive plate structures 82 are formed. In some embodiments, the third conductive plate structures 84 comprise a conductive material (e.g., tungsten) having a lower resistivity than the conductive material of the second conductive plate structures 82. In additional embodiments, the additional sacrificial structures 74 (FIGS. 17 through 19) are removed (e.g., stripped) before forming the second conductive plate structures 82 and the third conductive plate structures 84. The second conductive plate structures 82 and the third conductive plate structures 84, in some embodiments, are formed as unitary (e.g., monolithic) structures.

With continued reference to FIG. 20, an eighth offset O₈ is shown and defines a spaced apart offset region between top surfaces of the first conductive plate structures 69 and bottom surfaces of the second conductive plate structures 82. The eighth offset O₈ of the offset region may be within a range of from about 5 nm to about 15 nm (e.g., about 10 nm). As shown in FIG. 20, portions of each of the second insulative structures 73 and the resistive structures 78 are positioned between the first conductive plate structures 69 and the second conductive plate structures 82 in the offset region at least partially defined by the eight offset O₈. The resistivity of the material from which the resistive structures 78 are formed, the electrical properties (e.g., resistivity, dielectric constant, dielectric strength) of the material from which the second insulative structures 73 are formed, and/or the second depths D₂ thereof, as well as the separation distance between the first conductive plate structures 69 and the second conductive plate structures 82, at least partially defined by the eight offsets O₈, may be selected to tailor the resistance across the offset region between the first conductive plate structures 69 and the second conductive plate structures 82 as warranted for a particular application of a microelectronic device 200 resulting from the process stages described herein with reference to FIGS. 1 through 20. A degree of coupling between features of the microelectronic device 200 may be controlled via a preselected resistance across the offset region, in part, through appropriate selection of one or more of the aforementioned materials and parameters.

The microelectronic device 200 includes multiple storage node structures 86 respectively being defined by a combination of a first conductive plate structure 69, a second conductive plate structure 82, a third conductive plate structure 84, a second insulative structure 73, and a resistive structure 78. For an individual storage node structure 86, the second insulative structure 73 thereof may be horizontally interposed between the first conductive plate structure 69 and a portion of the resistive structure 78, and the third conductive plate structure 84 thereof in the Y-direction; the resistive structure 78 thereof may vertically overlie the first conductive plate structure 69 in the Z-direction, and may be horizontally interposed between the second conductive plate structure 82 and a portion of the second insulative structure 73, and remainders of the modified first insulative structures 23′ in the Y-direction. Further, the microelectronic device 200, as shown in FIG. 20, includes multiple memory cells 90, wherein an individual memory cell 90 includes one of the storage node structures 86 and one of access devices 18 coupled to the one of the storage node structures 86.

The methods described herein may be used to form microelectronic devices having insulative projections between neighboring first conductive plate structures (e.g., bottom electrodes) minimizing parasitic capacitance therebetween. In addition, insulative and resistive structures disposed between first and second conductive plate structures (e.g., between top and bottom electrodes) define preselected resistances therebetween to control coupling between features of microelectronic devices of the disclosure. The methods described herein may simplify the manufacture of microelectronic devices relative to conventional methods by eliminating the need for atomic layer etching between neighboring first conductive plate structures.

A microelectronic device including first insulative structures, each first insulative structure including first sections individually having a first horizontal width in a first direction, and second sections horizontally alternating with the first sections in a second direction orthogonal to the first direction, the second sections individually having a second horizontal width in the first direction greater than the first width. First conductive structures are directly adjacent the first sections of the first insulative structures in the first direction and directly adjacent the second sections of the first insulative structures in the second direction. Second insulative structures are directly adjacent the first conductive structures and the second sections of the first insulative structures in the first direction; and second conductive structures are directly adjacent the second insulative structures in the first direction.

A method of forming a microelectronic device includes forming first insulative structures each respectively including first sections individually having a first horizontal width in a first direction, and second sections horizontally alternating with the first sections in a second direction orthogonal to the first direction, the second sections individually having a second horizontal width in the first direction greater than the first width. The method also includes forming first conductive structures directly adjacent the first sections of the first insulative structures in the first direction and directly adjacent the second sections of the first insulative structures in the second direction. The method further includes forming second insulative structures directly adjacent the first conductive structures and the second sections of the first insulative structures in the first direction, and forming second conductive structures directly adjacent the second insulative structures in the first direction.

A memory device including an access device region with vertical access devices, and a storage node device region vertically overlying the access device region and having insulative structures each including sections having a first width in a first horizontal direction, and additional sections horizontally alternating with the sections in a second horizontal direction orthogonal to the first horizontal direction, the additional sections individually having a second width in the first horizontal direction greater than the first width. Storage node devices directly adjacent the insulative structures in the first horizontal direction and coupled to the vertical access devices to form memory cells, the storage node devices each including a bottom electrode directly adjacent one of the sections of one of the insulative structures in the first horizontal direction and directly adjacent one of the additional sections of the one of the insulative structures in the second horizontal direction. An additional insulative structure directly adjacent the bottom electrode and the one of the additional sections of the one of the insulative structures in the first horizontal direction, and a top electrode structure directly adjacent the additional insulative structure in the first horizontal direction.

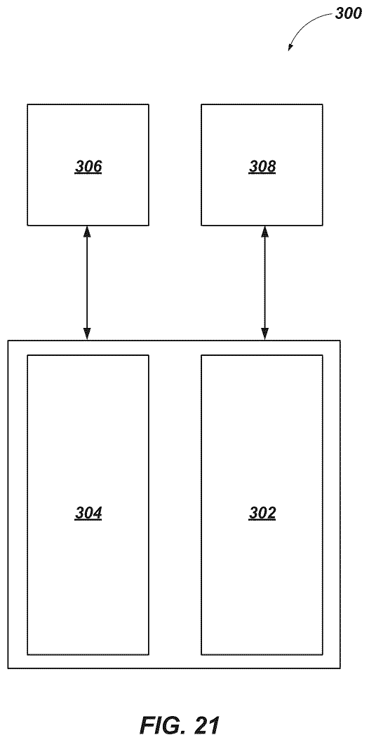

Microelectronic devices (e.g., the microelectronic device 200 shown in FIG. 20) including microelectronic device structures in accordance with embodiments of the disclosure may be used in embodiments of electronic systems of the disclosure. For example, FIG. 21 is a block diagram of an illustrative electronic system 300 according to embodiments of disclosure. The electronic system 300 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 300 includes at least one memory device 302. The memory device 302 may comprise, for example, an embodiment of a microelectronic device (e.g., the microelectronic device 200 shown in FIG. 20) previously described herein. The electronic system 300 may further include at least one electronic signal processor device 304 (often referred to as a “microprocessor”). The electronic signal processor device 304 may, optionally, include an embodiment of a microelectronic device (e.g., the microelectronic device 200 shown in FIG. 20) previously described herein. While the memory device 302 and the electronic signal processor device 304 are depicted as two (2) separate devices in FIG. 20, in additional embodiments, a single (e.g., only one) memory/processor device having the functionalities of the memory device 302 and the electronic signal processor device 304 is included in the electronic system 300. In such embodiments, the memory/processor device may include an embodiment of a microelectronic device structure previously described herein, and/or an embodiment of a microelectronic device (e.g., the microelectronic device 200 shown in FIG. 20) previously described herein. The electronic system 300 may further include one or more input devices 306 for inputting information into the electronic system 300 by a user, such as, for example, a mouse or other pointing device, a keyboard, a touchpad, a button, or a control panel. The electronic system 300 may further include one or more output devices 308 for outputting information (e.g., visual or audio output) to a user such as, for example, a monitor, a display, a printer, an audio output jack, a speaker, etc. In some embodiments, the input device 306 and the output device 308 may comprise a single touchscreen device that can be used both to input information to the electronic system 300 and to output visual information to a user. The input device 306 and the output device 308 may communicate electrically with one or more of the memory device 302 and the electronic signal processor device 304.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. A microelectronic device, comprising:
first insulative structures respectively comprising:
first sections individually having a first horizontal width in a first direction; and
second sections horizontally alternating with the first sections in a second direction orthogonal to the first direction, the second sections individually having a second horizontal width in the first direction greater than the first horizontal width;
first conductive structures directly adjacent the first sections of the first insulative structures in the first direction and directly adjacent the second sections of the first insulative structures in the second direction;
second insulative structures directly adjacent the first conductive structures and the second sections of the first insulative structures in the first direction; and
second conductive structures directly adjacent the second insulative structures in the first direction.

2. The microelectronic device of claim 1, further comprising resistive structures vertically overlying and horizontally overlapping the first conductive structures, the resistive structures horizontally interposed between the first sections of the first insulative structures and the second insulative structures in the first direction.

3. The microelectronic device of claim 2, further comprising third conductive structures vertically overlying and horizontally overlapping the second insulative structures, the third conductive structures horizontally interposed between the resistive structures and the second conductive structures in the first direction.

4. The microelectronic device of claim 3, wherein the third conductive structures are directly adjacent the resistive structures and the second sections of the first insulative structures in the first direction.

5. The microelectronic device of claim 1, wherein the second insulative structures comprise ferroelectric material.

6. The microelectronic device of claim 1, wherein the first insulative structures respectively exhibit arcuate transitions between the first sections and the second sections thereof.

7. The microelectronic device of claim 1, wherein upper surfaces of the first conductive structures vertically underlie upper surfaces of the second insulative structures.

8. The microelectronic device of claim 7, wherein upper surfaces of the second conductive structures vertically overlie the upper surfaces of the second insulative structures.

9. The microelectronic device of claim 8, wherein the upper surfaces of the second conductive structures are substantially coplanar with upper surfaces of the first insulative structures.

10. A method of forming a microelectronic device, comprising:
forming first insulative structures respectively comprising:
first sections individually having a first horizontal width in a first direction; and
second sections horizontally alternating with the first sections in a second direction orthogonal to the first direction, the second sections individually having a second horizontal width in the first direction greater than the first horizontal width;
forming first conductive structures directly adjacent the first sections of the first insulative structures in the first direction and directly adjacent the second sections of the first insulative structures in the second direction;
forming second insulative structures directly adjacent the first conductive structures and the second sections of the first insulative structures in the first direction; and
forming second conductive structures directly adjacent the second insulative structures in the first direction.

11. The method of claim 10, wherein forming the first insulative structures comprises:
forming preliminary first insulative structures horizontally extending in parallel in the second direction;
forming first masking structures over the first insulative structures and horizontally extending in parallel in the first direction;
etching portions of preliminary first insulative structures using the first masking structures as an etch mask to form the first insulative structures, the first masking structures at least partially horizontally overlapping the second sections of the first insulative structures in the second direction; and
removing remaining portions of the first masking structures after forming the first insulative structures.

12. The method of claim 10, further comprising forming arcuate transitions between the first sections and the second sections of the first insulative structures.

13. The method of claim 10, wherein forming the first conductive structures comprises:
forming a first conductive material to substantially cover and extend between the first insulative structures; and
removing portions of the first conductive material to form the first conductive structures, outer side surfaces of the first conductive structures substantially coplanar with outer side surfaces of the second sections of the first insulative structures in the first direction.

14. The method of claim 10, wherein forming the second insulative structures comprises:
forming ferroelectric material to substantially cover exposed surfaces of the first conductive structures and the first insulative structures; and
removing portions of the ferroelectric material on vertically uppermost surfaces of the first conductive structures and the first insulative structures while maintaining portions of the ferroelectric material on side surfaces of the first conductive structures and the second sections of the first insulative structures.

15. The method of claim 10, further comprising, before forming the second conductive structures:
vertically recessing the first conductive structures after forming the second insulative structures to form recesses horizontally between the first sections of the first insulative structures and the second insulative structures in the second direction; and
forming resistive structures in the recesses.

16. The method of claim 15, further comprising, before forming the second conductive structures:
vertically recessing the second insulative structures, after forming the resistive structures, to form additional recesses; and
forming additional conductive structures in the additional recesses, the additional conductive structures directly adjacent the resistive structures and the second sections of the first insulative structures in the first direction.

17. The method of claim 16, further comprising forming lower surfaces of the additional conductive structures to vertically overlie lower surfaces of the resistive structures.

18. The method of claim 16, wherein forming the second conductive structures comprises:
forming sacrificial structures directly adjacent the second insulative structures in the first direction prior to vertically recessing the second insulative structures; and
replacing the sacrificial structures with the second conductive structures after forming the additional conductive structures.

19. A memory device, comprising:
an access device region comprising vertical access devices; and
a storage node device region vertically overlying the access device region and comprising:
insulative structures respectively comprising:
sections each having a first width in a first horizontal direction; and
additional sections horizontally alternating with the sections in a second horizontal direction orthogonal to the first horizontal direction, the additional sections individually having a second width in the first horizontal direction greater than the first width; and
storage node devices directly adjacent the insulative structures in the first horizontal direction and coupled to the vertical access devices to form memory cells, the storage node devices respectively comprising:
a bottom electrode directly adjacent one of the sections of one of the insulative structures in the first horizontal direction and directly adjacent one of the additional sections of the one of the insulative structures in the second horizontal direction;
an additional insulative structure directly adjacent the bottom electrode and the one of the additional sections of the one of the insulative structures in the first horizontal direction; and
a top electrode structure directly adjacent the additional insulative structure in the first horizontal direction.

20. The memory device of claim 19, wherein the memory cells comprise one or more of dynamic random-access memory (DRAM) cells, high-resistive random-access memory (HRAM) cells, ferroelectric random-access memory (FeRAM) cells, synchronous dynamic random-access memory (SDRAM) cells, and resistive random-access memory (RRAM) cells.
